(19) United States
(12) Patent Application Publication
(10) Pub. No.: US 2004/0199847 A1
(43) Pub. Date: Oct. 7, 2004

(54) Method and apparatus for improving the performance of concatenated codes

(76) Inventors: Stefano Calabro, Muenchen (DE); Andreas Farbert, Muenchen (DE); Bernhard Spinnler, Muenchen (DE); Nebojsa Stojanovic, Muenchen (DE)

Correspondence Address: BELL, BOYD & LLOYD, LLC, P. O. BOX 1135, CHICAGO, IL, 60690-1135, US

(21) Appl. No.: 10/429,581

(22) Filed: May 5, 2003

(30) Foreign Application Priority Data
Mar. 5, 2003 (EP) 02009987.5

(51) Int. Cl. H03M 13/00

(52) U.S. Cl. 714/755

(57) ABSTRACT

The performance of concatenated codes are improved by generating check bits from information bits, which are represented by an information matrix, by an outer code. The information bits and the check bits are cyclically shifted to obtain an interleaved code matrix. Then, the bits of the interleaved code matrix are coded by an inner code, where at least the outer code, or the inner code, is a product code.

### BACKGROUND OF THE INVENTION

The capacity of optical transmission systems has rapidly increased in the last several years. The ability to upgrade a low bit-rate system to a higher bit-rate system by improving the optical components and compensating the limiting physical effects was the key for achieving system evolution.

The introduction of error control coding (ECC) was a very efficient tool that successfully improved the performance and reliability of digital data transmission. Adding redundancy check bits to the information bits and advanced decoding provided the possibility of increasing the transmission distance and further made the system more robust to adverse conditions that had impaired transmission performance, such as temperature variations and acoustic vibrations. Due to reasons of complexity, hard decoding was preferred to soft decoding. Codes such as Bose-Chaudhuri-Hocquenghem codes (BCH) or extended BCH codes, which can be implemented relatively easily, were preferred.

To improve coding gain, concatenated codes were introduced. However, this group of codes tends to be very sensitive when certain error patterns are received. Such error patterns cannot be corrected and, thus, lead to an insufficient bit error rate, which is also known as error flaring. This will be explained later in detail although a basic understanding of product coding may be surmised from the book “Prüfbare und korrigierbare Codes” W. Wesley Peterson, Oldenburg Verlag 1967, pages 117-123 or its English edition.

What is needed is a technique for improving the performance of concatenated codes while at the same time alleviating the problem of error flaring.

### SUMMARY OF THE INVENTION

Accordingly, the present invention provides a method for improving the bit error rate (BER) and, therefore, the coding gain. This is achieved according to one embodiment of the present invention by applying an outer encoding procedure, then interleaving the information bits and at least a group of check bits. Next, the present invention applies an inner encoding procedure, wherein at least one of the outer or inner code is a product code.

In another embodiment of the present invention, the interleaver is provided with a relatively low design complexity and memory requirements. A manner in which this is achieved by the present invention is that the first column of a two dimensional product code remains unchanged while the bits of the following columns are cyclically shifted by one, two, three, etc. positions, so that the bits of the first row are translated into diagonal bits by the interleaver.

Applying the described interleaving procedure both on columns and rows of a two dimensional product code breaks the error bursts in rows and in columns, with which the present invention further improves the coding gain.

Additional features and advantages of the present invention are described in, and will be apparent from, the following Detailed Description of the Invention and the Figures.

### BRIEF DESCRIPTION OF THE FIGURES

FIG. 1 is a schematic of a concatenated coding system.

FIG. 2 is a schematic of a two-dimensional product code.

FIG. 3 shows a permanent error-pattern.

FIG. 4 shows a two-dimensional code matrix;

FIG. 5 shows exemplary bits of a code matrix.

FIG. 6 shows exemplary bits of an interleaved code matrix.

FIG. 7 shows a final code matrix.

FIG. 8 shows an iterative decoding scheme.

FIG. 9 shows an error probability of an enhanced product code.

FIG. 10 is a schematic of the resulting matrix after two dimensional interleaving.

### DETAILED DESCRIPTION OF THE INVENTION

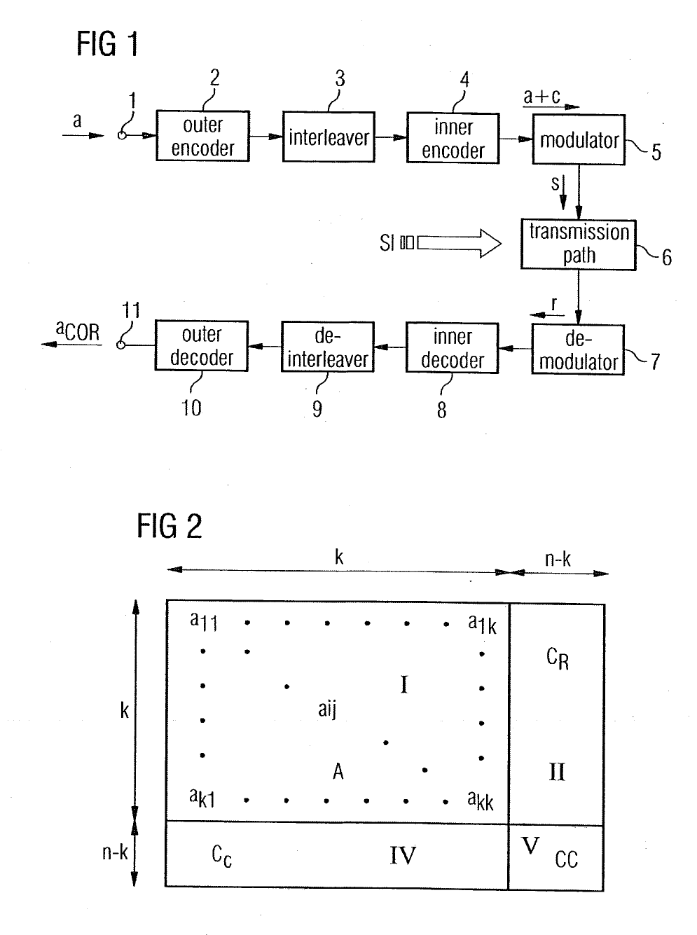

FIG. 1 shows a schematic of a transmission system with a concatenated code implementation. The information bits “a” are fed to the input 1 of an outer encoder 2, which is the first element of a serial concatenation including an interleaver 3 and an inner encoder 4. At least one of the codes is a product code, whereas the other code may be either a simple code or a concatenated code itself. The information bits “a” and the generated check bits “c” are fed to a modulator 5, which converts the bits into physical signals “s”, which are then transmitted over the transmission path 6 to a demodulator 7 at the receiving side.

Because of the non-ideal transmission path, the signals have a tendency to be disturbed by signal impairments SI; e.g., external perturbations or physical effects of the transmission path.

Thus, when the demodulator 7 converts the received signals into (binary) bits “r”, some of the resulting bit signal would be erroneous. The bits “r” are fed to a serial concatenation of an inner decoder 8, a deinterleaver (inverse interleaver) 9 and an outer decoder 10. The corrected information bits a_{COR} are emitted at the output 11.

Before turning to details of the present invention, it is useful to consider the construction of the matrices regarding the product code. In FIG. 2, a code word of a two-dimensional product code is shown. This may be generated by the outer encoder 2. The code word matrix has the dimension of n×n bits and contains k×k information bits in section I, the generated column check bits C_{C} in section IV and row check bits C_{R} in section II allow the correction of at least one error for each column or row. Checks on check-bits CC arranged in section V can be used for checking the check-bits C_{C} and C_{R}. Of course, a non-square code word matrix and different codes can be used for rows and columns.

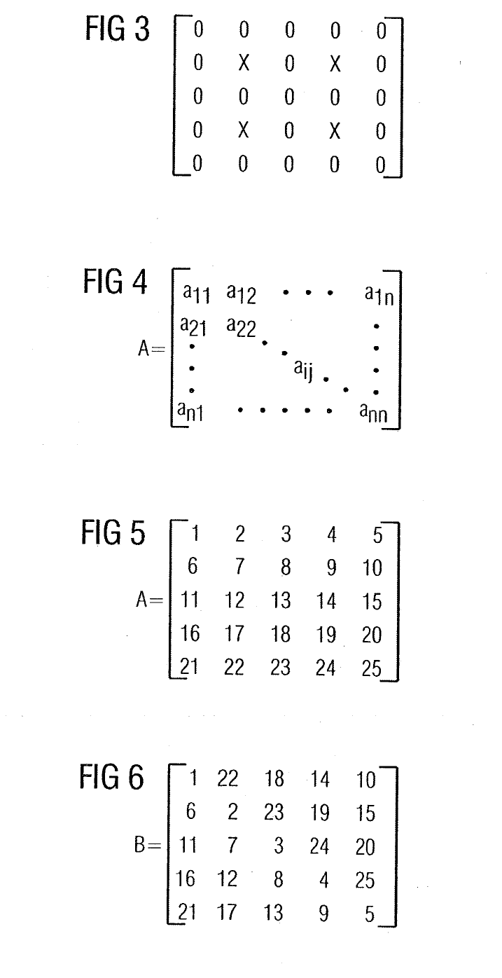

In FIG. 3, an example of a permanent 4-error-event for a 2D (two dimensional) product code with one-error-correcting codes as component codes is shown. FIG. 3 shows the case in which two errors occur in a row or column. If this occurs, a component one-error-correcting code would become overloaded and its decoder would, with high probability, add new errors. If that happens, the product code also would be overloaded because all of the errors occur in exactly two columns and two rows. Hence, the errors would never be corrected by the product code alone, no matter how many iterations are used. The error pattern would be permanent and would lead to error flaring. For component codes that can correct two or more errors, corresponding permanent error patterns exist.

However, such error patterns, which are permanent with regard to the product code alone, may be resolved in the overall concatenation thanks to the interleaver and the inner coding and decoding stages of the present invention. We consider the product code word in the general form of FIG. 4. The bits a₁₁ . . . aᵢⱼ . . . aₙₙ form a 2-dimensional code word or code word matrix. As will be explained, the interleaver 3 shown in FIG. 1 maps the matrix A into a matrix B defined by the equation,

b(i,j)=a((n+i−j)modn+1,j). (1)

Now, in more detail, FIG. 5 shows the original matrix A and FIG. 6 the “interleaved” matrix B with exemplary bits, which may help to understand this operation. All binary bits aᵢⱼ in FIG. 5 and bᵢⱼ in FIG. 6 are represented by natural numbers, representing their original bit sequence. In the interleaving process, regarding matrix A, the bits 1, 6, 11, 16, 21 of the first column remain in their positions; the bits 2, 7, 12, 17, 22 of the second column are shifted downwards cyclically by one position; the bits of the third column are cyclically shifted by two positions and so on. Matrix A is translated to matrix B as shown in FIG. 6. An interleaver performing this procedure is encompassed by the present invention.

The corresponding deinterleaver is described by the equation

a(i,j)=b((i+j−2)modn+1,j). (2)

After interleaving, an additional inner code is used for encoding matrix B.

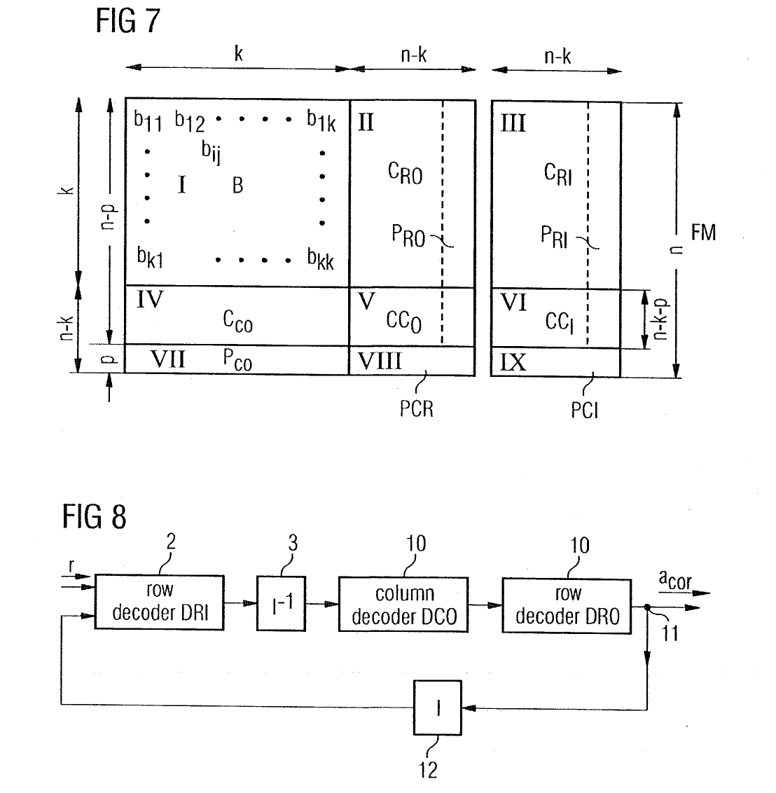

The resulting code matrix FM in more general form is shown in FIG. 7, for the case that the outer code is a product code and the inner code is a simple (non-concatenated) block code. To show the coding scheme more clearly, the result of the interleaving procedure is not shown. The overall encoding procedure is described in more detail in the following.

According to FIG. 1, the information bits aᵢⱼ, that are organized in the matrix A (FIG. 2), are fed to the outer encoder 2, which is an encoder for a 2D (two dimensional) product code. The component code for the realization of the outer product code is obtained by extending a base cyclic code. Check bits associated with the base code are denoted in FIG. 7 by C, whereas additional check bits (e.g. parity) of the extended code are denoted by P.

Corresponding to FIG. 7, the row check bits C_{RO}, separately generated for each row of information matrix A by the outer code, are represented in section II. Further, the column check bits C_{CO} of the columns, separately generated for each column by the outer code, are represented in section IV. Additional parity bits P_{RO}, P_{CO} are generated for rows and columns to improve the error detecting capability of the code. The column parity bits P_{CO} are presented in a separate section VII. The row parity bits P_{RO} are embedded in sections II and V.

Check on check-bits CC_{O} (inclusive associated parity bits P_{RO}) are generated and positioned in section V (because of linearity, the check on check bits in section V are also check on check bits of section IV). The column parity bits PCR of sections II and V are presented in section VIII.

After the outer encoding, wherein the sections II, IV, V, VII and VIII are generated, the sections I and IV are interleaved according to equation (1) by, for example, interleaver 3 of FIG. 1. The “A, C_{C}” matrix shown in FIG. 2 at the input of the interleaver 3 has the dimension (n−p)×k according to sections I and IV of FIG. 7. By shifting the columns of sections I and IV, an “interleaved” code-matrix B, C_{CO} (FIG. 7) is obtained.

Contrary to the reality, the interleaver did not alter the bits in section I and IV as shown in FIG. 7. Therefore, FIG. 7 still shows the information bits and check bits in their former sections, but the bits as are renamed into bits bᵢⱼ. Further, also the “interleaved” column check bits C_{CO} are still shown in form in section IV to avoid the confusing sequence of information and check bits as shown in FIG. 6.

In this example, the interleaver does not alter the remaining sections II, V, VII and VIII.

After interleaving sections I and IV, the inner encoder 4 of FIG. 1 encodes row-wise the bits of sections I and IV. The generated inner code check bits C_{RI} and check on check bits CC_{I} are represented in sections III and VI. The additional parity bits of the encoded rows P_{RI} are represented also in sections III and VI. Additional column check (parity) bits P_{CI}, derived from sections III and VI, are mapped into section IX. This encoding procedure assures that every bit of the code words, except the (n−k)×p bits of section IX, is encoded at least twice.

Thus, according to the present invention, wherein extended cyclic codes are used as component codes, the columns in section I and IV represent valid code words of the base code before and after interleaving. After the inner encoding stage, the rows of the combined sections I and III and the rows of the combined sections IV and VI similarly represent valid code words. Hence, due to the linearity, the columns of section III and VI are also valid code words. Because of the linearity of the codes, this coding scheme requires a moderate amount of redundant check bits.

The described coding scheme is only an example of the present invention. Of course, rows and columns of the code matrix can be interchanged and the outer and the inner code can be interchanged. The sequence of the transmitted bits should always be considered. If burst errors occur in an example according to FIG. 7, then either the transmitted bits should be transmitted in the following sequence b₁₁, b₂₁, . . . bₖ₁; b₁₂, b₂₂, . . . ,bₖ₂; . . . , or, instead of the rows, the columns should be protected by the inner code.

Several iterative decoding strategies can be devised according to the present invention. An example is shown in FIG. 8, wherein the decoding procedure provides good suppression of error flaring. The decoding device is the serial connection of the “inner row decoder” (DRI) 8, the deinterleaver 9, and an outer decoder 10, which is separated in an “outer column decoder” DCO and an “outer row decoder” DRO.

At the beginning of the decoding process, the inner decoder, the row decoder DRI, after receiving the final code matrix FM decodes n-p interleaved rows (sections I and III, II, V; IV and VI). The last p rows PCI are not valid code words, and hence are not processed. Thereafter, sections I and IV are deinterleaved (function I⁻¹).

The outer column decoder DCO (first section of the outer decoder 10) decodes all n columns in sections I, IV, and VII, in sections II, V, and VIII, and in sections III, VI, and IX.

The outer row decoder DRO (second section of the outer decoder 10) decodes all n rows; namely, the combined rows of sections I and II, IV and V, and VII and VIII. Herewith, the first iteration is finished.

After each decoding iteration, the corrected bits are transformed into the form of the final code matrix FM by an additional interleaver 12 (function I) and fed to the inner row decoder 2 again. After several iterations, the decoding process is stopped.

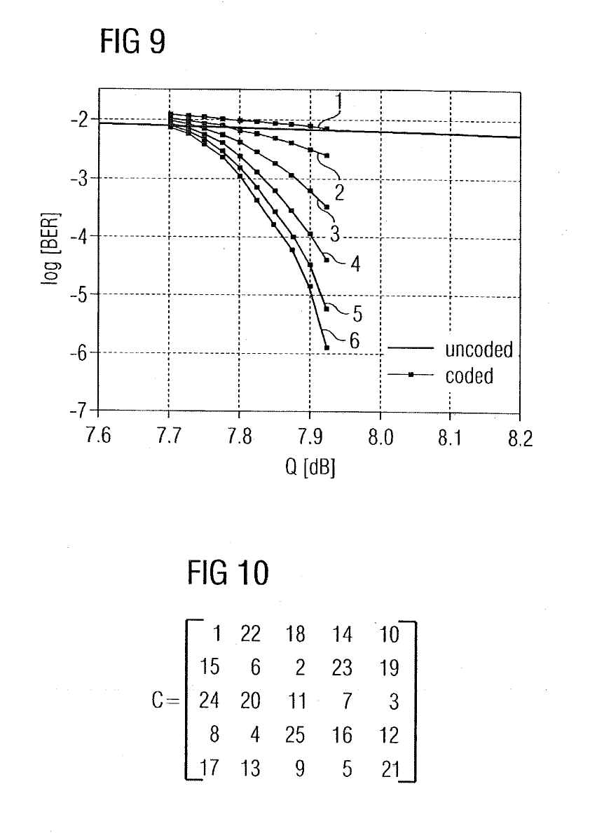

As an example, an extended BCH code (n=256, k=239, d=6) is used both as component code for the outer product code and as inner code. The base BCH code (255, 239) is extended by one additional parity bit, hence p=1 in this case. The simulated bit error rate BER is shown in FIG. 9 for consecutive iterations 1-6.

For breaking error bursts in rows and in columns, a second interleaver, respectively a two-dimensional interleaver, can be used between the inner and outer encoding stages. After being shifted cyclically, the resulting columns are shown in the example of FIG. 6, wherein all rows are shifted by 0, 1, 2, 3, etc., positions. The resulting matrix C is shown in FIG. 10, with the operation of the row-interleaver being described by the following equation:

c(i,j)=b(i,(n+i−j)modn+1). (3)

The function of a deinterleaver is described by the equation:

b(i,j)=c(i,(i+j−2)modn+1). (4)

The function of the two-dimensional interleaver can be described by the equation:

c(i,j)=a((n+2i−j−i)modn+1,(n+−i)modn+1) (5)

The function of the two-dimensional deinterleaver can be described by the function:

a(i,j)=c((i+j−2)modn+1,(i+2j−3)modn+1).

In the case of a combined two dimensional interleaver, n should be an odd number.

While the present invention according to FIG. 10 has been described with reference to specific equations, it goes without saying that the present invention encompasses the more general concept of a concatenated code that alleviates a burst error, and encompasses other equations that fulfil the aforementioned steps and operations.

As will be appreciated from the foregoing, the present invention provides a concatenated code that alleviates the effect of a burst error. Further, the present invention provides a system for encoding and a code therefor that is redundant and, therefore, minimizes the structure needed for encoding and decoding.

Although the present invention has been described with reference to specific embodiments, those of skill in the art will recognize that changes may be made thereto without departing from the spirit and scope of the present invention as set forth in the hereafter appended claims.

1. A method for improving performance of concatenated codes, the method comprising the steps of:
generating check bits from information bits, which are represented by an information matrix, as a result of an outer code being applied to the information bits;
interleaving the information bits and at least a portion of the check bits by shifting the bits cyclically in different columns/rows by a value that is different for each column/row to obtain an interleaved code matrix; and
encoding the bits of the interleaved code matrix using an inner code, wherein at least one of the outer code and the inner code is a product code.

2. A method for improving performance of concatenated codes as claimed in claim 1, wherein the step of generating check bits includes encoding columns/rows and rows/columns of the information bits that are represented in the information matrix by the outer code in order to generate column check bits of each column and row check bits of each row, and wherein the step of interleaving includes interleaving the information bits and at least the column/row check bits.

3. A method for improving performance of concatenated codes as claimed in claim 1, wherein the bits of a first column/row are not shifted and the bits of the respectively following columns/rows are cyclically shifted by different positions.

4. A method for improving performance of concatenated codes as claimed in claim 1, wherein the bits of a last column/row are not shifted and the bits of the respectively forgoing columns/rows are cyclically shifted by different positions.

5. A method for improving performance of concatenated codes as claimed in claim 3, wherein the bits of each row/column are additionally cyclically shifted by different positions.

6. A method for improving performance of concatenated codes as claimed in claim 5, wherein the bits of a first row/column are not shifted and the bits of the respectively following rows/columns are cyclically shifted by different positions.

7. A method for improving performance of concatenated codes as claimed in 2, wherein the step of encoding further includes encoding column/row check bits by the outer code representing a product code to produce check on check bits.

8. A method for improving performance concatenated codes claimed in claim 7, the method further comprising the steps of:
generating additional column/row parity bits by the outer code for columns/rows; and
generating additional row/column parity bits by the outer code for rows/columns.

9. A method for improving performance of concatenated codes as claimed in claim 7, the method further comprising the step of encoding the interleaved code matrix by the inner code in order to generate inner row/column check bits of the interleaved information bits and of the dependent interleaved column/row check bits.

10. A method for improving performance of concatenated codes as claimed in claim 9, the method further comprising the steps of:
generating check on check bits of the interleaved code matrix; and
generating additional inner row/column parity bits of the interleaved code matrix and depending inner row/column check bits and check on check bits.

11. A method for improving performance of concatenated codes as claimed in claim 10, the method further comprising the step of generating inner column/row parity bits of the inner row/column check bits and the inner row/column parity bits.

12. A method for improving performance of concatenated codes as claimed in claim 1, the method further comprising the step of iterative decoding of each transmitted final code matrix, wherein the decoding steps are executed inversely to the encoding steps.

13. A method for improving performance of concatenated codes as claimed in claim 2, wherein interleaving and deinterleaving of the bits in columns and rows is performed via a two-dimensional interleaver and respective two-dimensional deinterleaver.

14. A concatenated code for alleviating effects of a burst error, comprising:
information bits represented by an information matrix;
check bits generated from the information bits, the check bits being encoded according to an outer code applied to the information bits; and
an interleaved code matrix, wherein the information bits and at least a portion of the check bits that are shifted cyclically in respectively different columns/rows by a value that is different for each column/row are interleaved to obtain the interleaved code matrix, the interleaved code matrix being encoded by an inner code, and wherein at least one of the outer code and the inner code is a product code.

15. An apparatus for improving performance of concatenated codes, comprising:
an outer encoder for encoding information bits, which are represented by an information matrix, using an outer code, and for generating check bits;
an interleaver for interleaving the information bits and at least a portion of the check bits by shifting the bits cyclically in different columns by a value that is different for each column to obtain an interleaved code matrix; and
an inner encoder for encoding the bits of the interleaved code matrix using an inner code, wherein at least one of the outer code and the inner code is a product code.

16. An apparatus for improving performance of concatenated codes as claimed in claim 15, wherein the outer encoder encodes columns/rows and rows/columns of the information bits that are represented in the information matrix by the outer code in order to generate column check bits of each column and row check bits of each row, and the step of interleaving interleaves the information bits and at least the respective column/row check bits.

17. An apparatus for improving performance of concatenated codes as claimed in claim 15, wherein the interleaver is arranged between the outer encoder and the inner encoder to provide that a code word to be encoded is valid before and after interleaving.

18. An apparatus for improving performance of concatenated codes as claimed in claim 15, wherein the interleaver is a two-dimensional interleaver.

19. An apparatus for improving performance of concatenated codes as claimed in claim 15, further comprising a decoder for decoding the concatenated codes encoded by the inner encoder.

20. An apparatus for improving performance of concatenated codes as claimed in claim 19, wherein the decoder includes a serial connection of an inner row decoder, a de-interleaver and an outer decoder.
